(19) United States
(12) Patent Application Publication
(10) Pub. No.: US 2003/0009723 A1
(43) Pub. Date: Jan. 9, 2003

(54) Simplified reed-solomon decoding circuit and method of decoding reed-solomon codes

(76) Inventor: Ta-Hsiang Chien, Hsinchu (TW)

Correspondence Address: NIXON PEABODY, LLP, 8180 GREENSBORO DRIVE, SUITE 800, MCLEAN, VA, 22102, US

(21) Appl. No.: 09/840,228

(22) Filed: Apr. 24, 2001

(51) Int. Cl. H03M 13/29

(52) U.S. Cl. 714/784

(57) ABSTRACT

In performing Reed-Solomon decoding, a Forney algorithm that is applied to find error magnitudes from information of error locations is simplified. A reduced syndrome polynomial together with an error locator polynomial is applied to calculate a simplified error-evaluator polynomial. Each element of the reduced syndrome polynomial is with an order less than a limit minus one, wherein the limit is less than twice of an error correcting capability. And elements of the simplified error-evaluator polynomial with an order higher than the limit are eliminated. An error polynomial is thus generated based on the reduced syndrome polynomial and the simplified error-evaluator polynomial.

### FIELD OF THE INVENTION

The present invention relates to a decoding circuit and method, and more particularly, to a simplified Reed-Solomon decoding circuit and a method of decoding Reed-Solomon codes.

### BACKGROUND OF THE INVENTION

Noises will commonly occur during data transmission, storage and recovery, and subsequently produce errors in data. Various techniques possessing capability of error correction have been developed to encode and decode the data to be transmitted or stored. Among such techniques, Reed-Solomon codes play an important role especially in the area of high-speed data transmission.

Reed-Solomon code is an important code that has been an integral part of telecommunication revolution for the past thirty years, and Forney algorithm is the most important algorithm for a typical Reed-Solomon decoder in finding error magnitudes from information of error locations with a very high speed.

Please refer to FIG. 1 in depicting a prior art Reed-Solomon decoder. A Reed-Solomon decoder 1 typically includes a syndrome calculator 11, an error locator polynomial calculator 12, an error polynomial calculator 13 and an error corrector 14.

The syndrome calculator 11 receives a message r′(x) to be decoded and error-corrected and generates a syndrome polynomial S(x). The error locator polynomial calculator 12 receives the syndrome polynomial S(x) and generates an error locator polynomial Λ(x). The error polynomial calculator 13 receives the error locator polynomial Λ(x) and the syndrome polynomial S(x), and based on the Forney algorithm calculates an error-evaluator polynomial Ω(x) (not shown in the figure) and generates an error polynomial e(x). The error corrector 14 corrects the message r′(x) by removing the error polynomial e(x) therefrom.

In prior art Reed-Solomon decoder and decoding method, the syndrome polynomial S(x) received by the error polynomial calculator 13 includes 2t elements, wherein t is an error correcting capability of the message r′(x). That is, each syndrome value of the polynomial S(x) with an order lower than (2t-1), particularly with an order between t and (2t-1), is sent to the error polynomial calculator 13. Such a number of 2t syndrome values results in more complex calculation and subsequently more hardware circuits and lower speed.

Furthermore, in prior art Reed-Solomon decoder and decoding method, each element of the error-evaluator polynomial Q (x) is not eliminated unless exceeding an order of 2t. Each element of the error-evaluator polynomial Q (x) with an order between t and 2t is reserved in calculating the error polynomial e(x). Similarly, such a number of error-evaluator polynomial elements will result in more complex calculation and subsequently more hardware circuits and lower speed.

It is desirable that the Forney algorithm can be simplified and so that the hardware circuits can be reduced and the decoding speed can be increased.

### SUMMARY OF THE INVENTION

It is found in the present invention that the Forney algorithm can be further simplified with less hardware circuits and meanwhile a faster speed can be achieved.

In the present invention, the Forney algorithm is simplified. A reduced syndrome polynomial together with an error locator polynomial is applied to calculate a simplified error-evaluator polynomial. Each element of the reduced syndrome polynomial is with an order less than a limit, wherein the limit is between t and 2t. And elements of the simplified error-evaluator polynomial with an order higher than the limit are eliminated. By reducing the number of syndrome values being sent to the error polynomial calculator and by reducing the number of error-evaluator polynomial elements being used to calculate the error polynomial, the Forney algorithm calculation is simplified. Therefore, the hardware circuit can be reduced, a smaller area of hardware and a faster speed can be achieved.

The present invention can be widely applied, but not limited to, in high-speed digital communication systems. The Reed-Solomon code defined in G. 992.1, G.992.2, and T1.413 for asymmetric digital subscriber loop (ADSL) application is a typical example of such application in wide-band high-speed telecommunication.

Advantages and spirit of the present invention can be further understood by the following detailed description of the invention and drawings.

### BRIEF DESCRIPTION OF THE DRAWINGS

FIG. 1 depicts a prior art Reed-Solomon decoder.

FIG. 2 depicts a Reed-Solomon decoder according to the present invention.

FIG. 3 depicts a step flow chart of a Reed-Solomon decoding method according to the present invention.

FIG. 4 depicts a common syndrome calculator.

FIG. 5 depicts an arithmetic unit commonly used in a Reed-Solomon decoder.

FIG. 6 depicts a selector of the present invention.

FIG. 7 depicts a simplified error polynomial calculator of the present invention.

FIG. 8 depicts another simplified error polynomial calculator of the present invention.

FIG. 9 depicts still another simplified error polynomial calculator of the present invention.

### DETAILED DESCRIPTION OF THE INVENTION

Please refer to FIG. 2 for description of a Reed-Solomon decoding circuit 2 of the present invention.

The Reed-Solomon decoding circuit 2 is for decoding a message r′(x) encoded by a Reed-Solomon code and for correcting errors therein. The Reed-Solomon code has an error correcting capability of t.

The Reed-Solomon decoding circuit 2 includes a syndrome calculator 21, an error locator polynomial calculator 22, a selector 23, a simplified error polynomial calculator 24, and an error corrector 25.

The syndrome calculator 21, in response to the message r′(x), generates a syndrome polynomial S(x) of the message r′(x). The error locator polynomial calculator 22, in response to the syndrome polynomial S(x), generates an error locator polynomial Λ(x). The syndrome calculator 21 and the error locator polynomial calculator 22 use the algorithms outlined in Wicker et al. (Stephen B. Wicker, and Vijay K. Bhargava, Reed-Solomon codes and Their Application, IEEE Press, 1994) and Shao et al. (Howard M. Shao, T. K. Truong, Leslie J. Deutsch, Joseph H. Yuen, and Irving S. Reed, VLSI Design of a Pipeline Reed-Solomon Decoder, IEEE Trans. on Comm., Vol. C-34. NO. 5, May 1985) without any simplification.

The selector 23, in response to the syndrome polynomial S(x), generates a reduced syndrome polynomial S′(x). Each element of the reduced syndrome polynomial S′(x) has an order less than a limit, wherein the limit is between t and 2t. The reduced syndrome polynomial S′(x) is sent to the simplified error polynomial calculator 24 for generation of an error polynomial e(x).

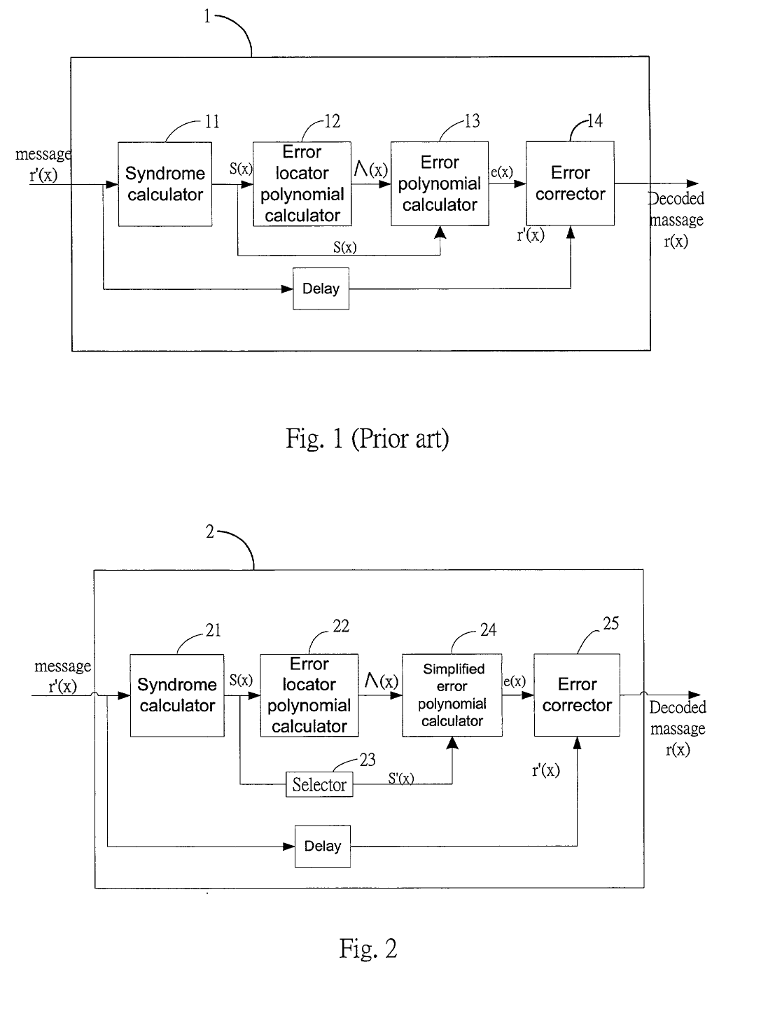

In prior art Reed-Solomon decoding circuit 1, as shown in FIG. 1, the syndrome polynomial S(x) is sent to the error polynomial calculator 13 for generation of the error polynomial e(x). Most elements of the syndrome polynomial S(x), including elements with orders between t and (2t-1), are sent to the error polynomial calculator 13. Totally a number of 2t elements are sent. Such a large number of the elements of the syndrome polynomial S(x) will add burdens on the error polynomial calculator 13. Calculation in the error polynomial calculator 13 is generally complex and time-consuming, and more hardware devices are required.

In the present invention, it is found that the number of elements of the syndrome polynomial being sent to the error polynomial calculator 24 can be further reduced. Therefore, the selector 23 is introduced to reduce the number of elements of the syndrome polynomial from 2t of the prior art decoding circuit to a number between t and 2t. Each element of the reduced syndrome polynomial S′(x) has an order less than the limit, wherein the limit is between t and 2t. In a preferred embodiment, the limit is set to t.

The simplified error polynomial calculator 24, in response to the error locator polynomial Λ(x) and the reduced syndrome polynomial S′(x), generates an error polynomial e(x). The algorithm applied in the simplified error polynomial calculator 24 is basically the Forney algorithm, which is described by Wicker (Stephen B. Wicker, Error Control Systems For Digital Communication And Store, N. J. 1995) and Blahut (Richard E. Blahut, Theory and Practice of Error Control Codes, MA (Massachusetts) 1983). However, the Forney algorithm is further simplified in the present invention.

In the Reed-Solomon decoding circuit 2 of the present invention, the simplified error polynomial calculator 24, in response to the error locator polynomial Λ(x) and the reduced syndrome polynomial S′(x), further generates a simplified error-evaluator polynomial Ω(x) for the generation of the error polynomial e(x). The error polynomial calculator 24 is further simplified by eliminating each element of the simplified error-evaluator polynomial Ω(x) with an order higher than the limit, which is between t and 2t.

In the prior art Reed-Solomon decoding circuit, the error-evaluator polynomial Ω(x) is defined as including elements with orders less than 2t, which means that the elements of the error-evaluator polynomial Ω(x) with orders between t and 2t are included in calculating the error polynomial e(x). However, in the present invention, it is found that the elements of the error-evaluator polynomial Q (x) required in calculating the error polynomial e(x) can be reduced no longer as high as 2t in order. Therefore, each element of the simplified error-evaluator polynomial Ω(x) with an order higher than the limit is eliminated, wherein the limit is between t and 2t.

Because of the reduced element numbers of the simplified error-evaluator polynomial Ω(x) and the reduced syndrome polynomial S′(x) in the simplified error polynomial calculator 24, calculation speed of the decoding circuit 2 of the present invention can be increased and hardware devices required therein can be reduced. The Reed-Solomon decoding circuit 2 of the present invention will be enhanced in speed performance and can be reduced in circuit area.

The error corrector 25, in response to the error polynomial e(x) and the message r′(x), generates a desired decoded message r(x). The message r′(x) is delayed in accordance with the calculation time before entering the error corrector 25. In the error corrector 25, the error polynomial e(x) is further removed from the message r′(x) and the decoded message r(x) is thus generated.

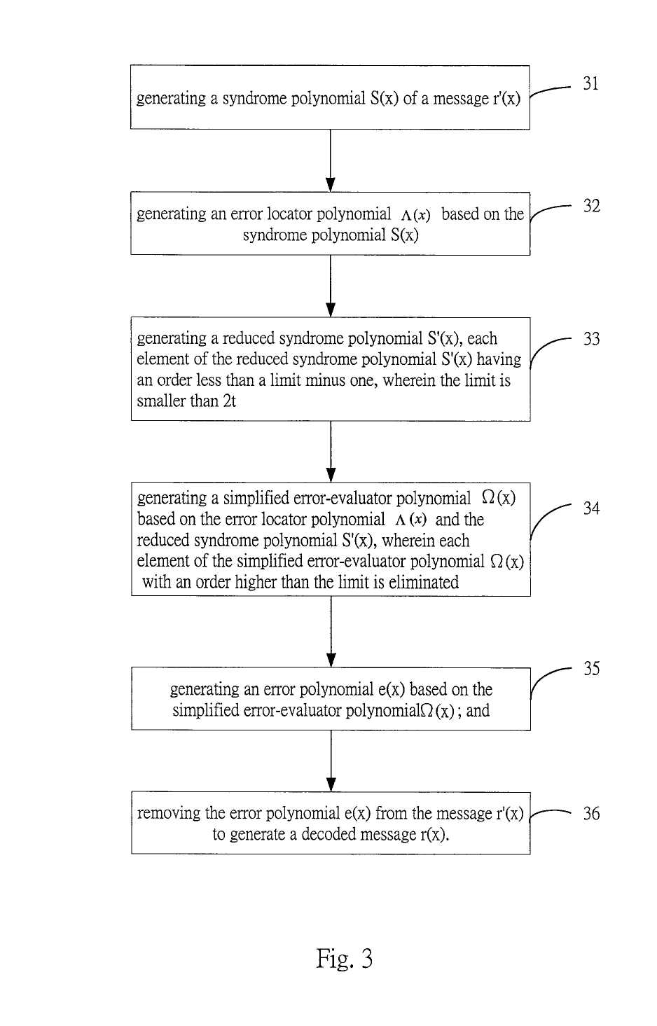

Please refer to FIG. 3, depicting a step flow chart of a Reed-Solomon decoding method according to a preferred method of the present invention. In a step 31, a syndrome polynomial S(x) of a message r′(x) is generated. In a step 32, an error locator polynomial A (x) is generated based on the syndrome polynomial S(x). In a step 33, a reduced syndrome polynomial S′(x) is generated. Each element of the reduced syndrome polynomial S′(x) has an order less than a limit, wherein the limit is between t and 2t. In a step 34, a simplified error-evaluator polynomial Ω(x) is generated based on the error locator polynomial Λ(x) and the reduced syndrome polynomial S′(x), wherein each element of the simplified error-evaluator polynomial Ω(x) with an order higher than the limit is eliminated. In a step 35, an error polynomial e(x) is generated based on the simplified error-evaluator polynomial Ω(x) and the roots of error locator polynomial Λ(x). And in a step 36, the error polynomial e(x) is removed from the message r′(x) to generate a decoded message r(x).

### EXAMPLE

Generation of a Syndrome Polynomial S(x) of the Message r′(x)

Let n=2^{k}-1 and GF(2^{k}) be the finite field for RS codes which include {0,1,α,α²,α³, . . . ,αⁿ⁻¹} elements.

Define Generator polynomial: G(x)=(x-1)(x-α) . . . (x-α^{2t-1})

Assuming that error polynomial of the received message r′(x) is given by

$$e ( x ) = {\sum }_{l = 0}^{v - 1} {e}_{l} {x}^{{i}_{l}}$$

The syndrome sequence can be expressed in terms of these errors and is defined as bellows:

$${S}_{j} = r ( {α}^{j} ) = e ( {α}^{j} ) = {\sum }_{i = 0}^{v - 1} {e}_{l} {α}^{{j}^{{i}_{l}}} = {\sum }_{i = 0}^{v - 1} {e}_{l} {X}_{l}^{j}$$

and the syndrome polynomial S(x) is defined as:

$$S ( x ) = {\sum }_{j = 0}^{2 t - 1} {S}_{j} {x}^{j} = {\sum }_{j = 0}^{2 t - 1} {\sum }_{l = 0}^{v - 1} {e}_{l} {X}_{l}^{j} {x}^{j}$$

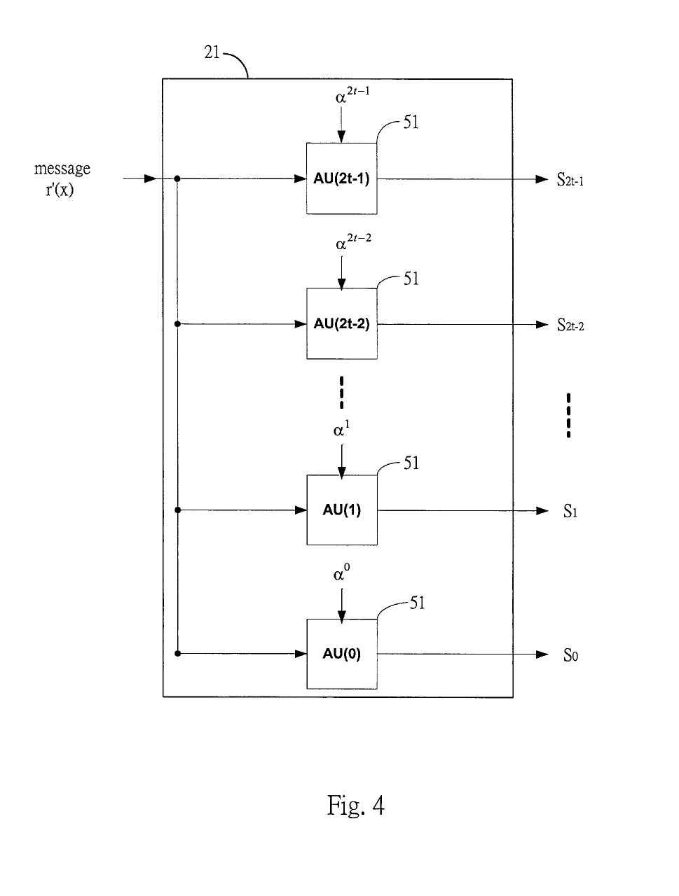

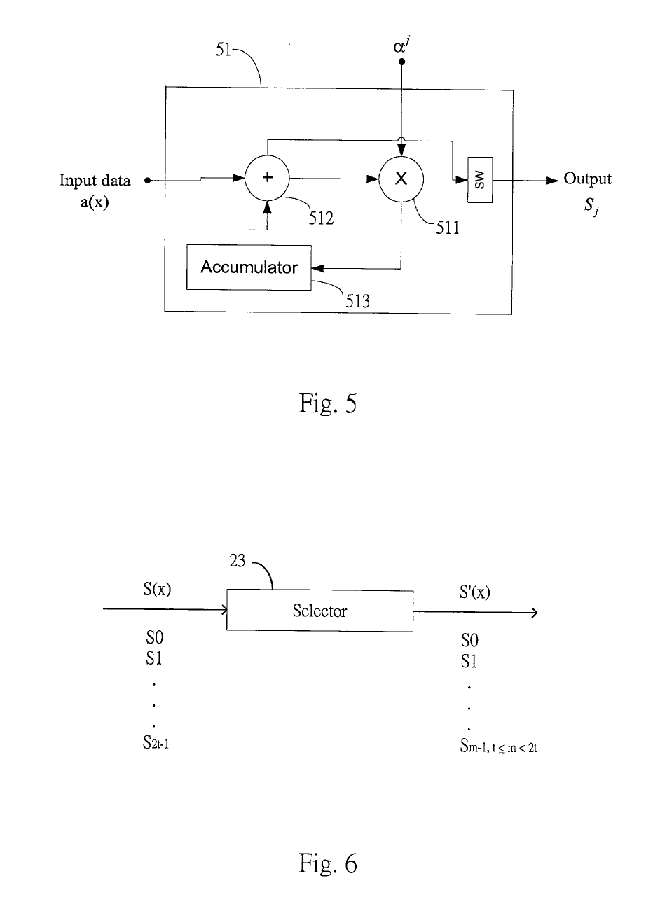

FIG. 4 depicts in detail the composition of the syndrome calculator 21. The message r′(x) is inputted to the syndrome calculator 21 and the syndrome polynomial S(x) including the elements from S₀ to S₂ₜ₋₁ are outputted. Each of arithmetic unit (AU) 51, as shown in FIG. 5, consists of a GF multiplier 511, an adder 512 and an accumulator 513. The arithmetic unit 51 is a fundamental element widely used in a RS decoder. The function of the arithmetic unit 51 is defined by the following equation:

$${S}_{j} = a ( {α}^{j} ) = {\sum }_{l = 0}^{M} {a}_{l} {α}^{{j}^{{i}_{l}}}$$

Wherein, M is the order of input data a(x).

Generation of an error locator polynomial Λ(x)

The error locator polynomial Λ(x) is obtained in the error locator polynomial calculator 22 from the syndrome polynomial S(x) using an algorithm commonly known as the Extended Euclidean algorithm, which is described by Wicker et al (Stephen B. Wicker, and Vijay K. Bhargava, Reed-Solomon codes and Their Application, IEEE Press, 1994) and Shao et al (Howard M. Shao, T. K. Truong, Leslie J. Deutsch, Joseph H. Yuen, and Irving S. Reed, VLSI Design of a Pipeline Reed-Solomon Decoder, IEEE Trans. on Comm., Vol. C-34. NO. 5, May 1985).

The error locator polynomial Λ(x) thus generated is sent to the simplified error polynomial calculator 24.

The error locations X₁ can be found in this step with the help of the following equation.

Λ(x)=Λᵥx^{v}+Λᵥ₋₁x^{v-1}+. . . +Λ₁x+1

which is defined to have zeros at X₁ for 1=1, . . . . ,v:

$$Λ ( x ) = {\prod }_{l = 0}^{v - 1} ( 1 - {X}_{l} x )$$

wherein X₁ for 1=1, . . .,v are errors' locations in a received data sequence of the message r′(x).

Generation of a Reduced Syndrome Polynomial S′(x)

Please refer to FIG. 6. The selector 23 reduces elements of the syndrome polynomial S(x) coming from the syndrome calculator 21 from a number of 2t to m, wherein m is the number of elements of the reduced syndrome polynomial S′(x) and m is smaller than 2t and not less than t. In other words, the syndrome polynomial S(x) is reduced by the selector 23 to the reduced syndrome polynomial S′(x) each element of which has an order less than (m-1), wherein t≦m<2t.

The reduced syndrome polynomial S′(x) is then sent to the simplified error polynomial calculator 24 for generation of error polynomial e(x).

Generation of an Error-Evaluator Polynomial Ω(x) and an Error Polynomial e(x)

In the Prior Art Decoder and Method

Before entering description and for better understanding of the generation of the error-evaluator polynomial Ω(x) and the error polynomial e(x) according to the present invention, it is necessary to describe in detail the prior art Forney algorithm as below.

In the prior art Reed-Solomon decoding method, error magnitudes e, is computed from the syndrome polynomial S(x) and the error-locator polynomial A(x). The process is described in the following.

The error-evaluator polynomial Ω(x) is defined as:

Ω(x)≡S(x)·Λ(x)(mod x^{2t})

Define the

It can be proved that

Wherein, each element of the error-evaluator polynomial Ω(x) with an order higher than 2t is eliminated. That is, the error-evaluator polynomial Ω(x) has 2t elements in number.

It can be proved that

$$\begin{matrix}Ω ( x ) = S ( x ) \cdot Λ ( x ) = [ {\sum }_{j = 0}^{2 t - 1} ( {\sum }_{i = 0}^{v - 1} {e}_{i} {X}_{i}^{j} ) {x}^{j} ] [ {\prod }_{l = 0}^{v - 1} ( 1 - {X}_{l} x ) ] \\ = {\sum }_{i = 0}^{v - 1} {e}_{i} [ ( 1 - {X}_{i} x ) {\sum }_{j = 0}^{2 t - 1} {( {X}_{i} x )}^{j} ] {\prod }_{l \neq i} ( 1 - {X}_{l} x ) \\ = {\sum }_{i = 0}^{v - 1} {e}_{i} ( 1 - {X}_{i}^{2 t} {x}^{2 t} ) {\prod }_{l \neq i} ( 1 - {X}_{l} x ) \\ ≡ {\sum }_{i = 0}^{v - 1} {e}_{i} {\prod }_{l \neq i} ( 1 - {X}_{l} x ) ( mod {x}^{2 t} )\end{matrix} \qquad ( 1 )$$

After the modulo operation by x^{2t}, each element of the error-evaluator polynomial Ω(x) with an order higher than 2t is eliminated and it's ready to obtain an expression for the error magnitudes.

$$Ω ( {X}_{k}^{- 1} ) = {\sum }_{i = 0}^{v - 1} {e}_{i} {\prod }_{l \neq i} ( 1 - {X}_{l} {X}_{k}^{- 1} ) = {e}_{k} {\prod }_{l \neq i} ( 1 - {X}_{l} {X}_{k}^{- 1} )$$

The derivative of Ω(x) is given by

$${Λ}^{′} ( x ) = - {\sum }_{i = 0}^{v - 1} {X}_{i} {\prod }_{l \neq i}^{v - 1} ( 1 - {X}_{l} x )$$

$$Thus , \\ {Λ}^{′} ( {X}_{k}^{- 1} ) = - {\sum }_{i = 0}^{v - 1} {X}_{i} {\prod }_{l \neq i}^{v - 1} ( 1 - {X}_{l} {X}_{k}^{- 1} )$$

The error magnitude eₖ is

$$\begin{matrix}{e}_{k} = - \frac{Ω ( {X}_{k}^{- 1} )}{{X}_{k}^{- 1} * {Λ}^{′} ( {X}_{k}^{- 1} )} \\ = - \frac{Ω ( {X}_{k}^{- 1} )}{{X}_{k}^{- 1} * - {X}_{k} {\prod }_{l \neq k} ( 1 - {X}_{l} {X}_{k}^{- 1} )} \\ = \frac{{e}_{k} {\prod }_{l \neq k} ( 1 - {X}_{l} {X}_{k}^{- 1} )}{{\prod }_{l \neq k} ( 1 - {X}_{l} {X}_{k}^{- 1} )} \\ = {e}_{k}\end{matrix} \qquad ( 2 )$$

After finding error locations and their associated error magnitudes, the error polynomial e(x) of the received messages r′(x) is obtained. The decoded message r(x) is thus given by removing the error polynomial e(x) from the received message r′(x) in the next step.

In the Present Invention—Simplification of Forney Algorithm

As mentioned previously, one of the major differences between the prior art RS decoding and the simplified RS decoding of the present invention is the simplified Forney algorithm. The simplification mainly focuses on the error-evaluator polynomial Ω(x). The procedure of this simplification in a preferred embodiment and its associated proof are shown as below.

Firstly, reduce the number of syndromes that are used in creating the simplified error-evaluator polynomial Ω(x) and reduce the syndrome polynomial S(x) as following.

$${S}^{′} ( x ) = {\sum }_{j = 0}^{t - 1} {S}_{j} {x}^{j} = {\sum }_{j = 0}^{t - 1} {\sum }_{i = 1}^{v} {e}_{i} {X}_{i}^{j} {x}^{j}$$

And secondly, the error-evaluator polynomial Ω(x) is also re-defined as

Ω(x)≡S(x)·Λ(x)(mod x^{t})

After these changes of definitions, the error magnitudes eₖ can be obtained in an easier way due to the fact that it now only needs “t” syndrome values Sⱼ and “t” error-evaluator polynomial elements Λⱼ to calculate eₖ instead of “2t” syndrome values Sⱼ and “2t” error-evaluator polynomial elements Ωⱼ in the prior art decoding process. The proof of their equivalence is outlined as follows:

$$\begin{matrix}Ω ( x ) = S ( x ) \cdot Λ ( x ) \\ = [ {\sum }_{j = 0}^{t - 1} ( {\sum }_{i = 0}^{v - 1} {e}_{i} {X}_{i}^{j} ) {x}^{j} ] [ {\prod }_{l = 0}^{v - 1} ( 1 - {X}_{l} x ) ] \\ = {\sum }_{i = 0}^{v - 1} {e}_{i} [ ( 1 - {X}_{i} x ) {\sum }_{j = 0}^{t - 1} {( {X}_{i} x )}^{j} ] {\prod }_{l \neq i} ( 1 - {X}_{l} x ) \\ = {\sum }_{i = 0}^{v - 1} {e}_{i} ( 1 - {X}_{i}^{t} {x}^{t} ) {\prod }_{l \neq i} ( 1 - {X}_{l} x ) \\ ≡ {\sum }_{i = 0}^{v - 1} {e}_{i} {\prod }_{l \neq i} ( 1 - {X}_{l} x ) ( m o d {x}^{t} )\end{matrix} \qquad ( 3 )$$

Comparing the equations (1) and (3), it can be easily found that these two equations are identical. Since the simplification does not cause any change to the result of the error-evaluator polynomial Ω(x), the error magnitude eₖ′ obtained from this simplified Forney algorithm will be the same as the error magnitude eₖ obtained from the prior art RS decoding. In addition, since the required syndromes and error-evaluator polynomial elements are reduced, the hardware area and number of numerical operations to implement this simplified RS decoding scheme are reduced correspondingly as compared with the original Forney algorithm based RS decoding process.

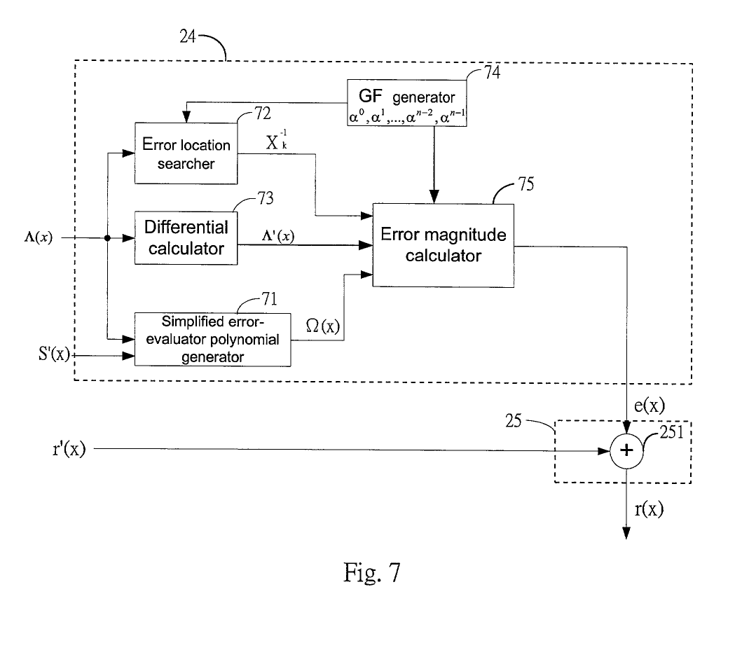

Please refer to FIG. 7 for detailed description of the error polynomial calculator 24 and the error corrector 25 according to an embodiment of the present invention.

In the error polynomial calculator 24, a simplified error-evaluator polynomial generator 71, an error location searcher 72, a differential calculator 73, a GF generator 74 and an error magnitude calculator 75 are mainly included. In the simplified error-evaluator polynomial generator 71, the reduced syndrome polynomial S′(x) and the error locator polynomial Λ(x) are introduced to generate the simplified error-evaluator polynomial Ω(x) in which elements with orders higher than t are eliminated based on the above equation (3).

In the error location searcher 72, elements of the inverse of error location Xₖ⁻¹ are generated based on the elements of the GF(Galois field) generator 74, α⁰ , α¹, . . . , αⁿ⁻¹. In the differential calculator 73, the error locator polynomial Λ(x) is differentiated to produce the derivative error locator polynomial Λ′(x). The error magnitude calculator 75 collects the resultant elements of the above devices and generates the error polynomial e(x) that is sent to the error corrector 25. An adder 251 in the error corrector 25 removes the error polynomial e(x) from the input message r′(x) and generates the decoded message r(x).

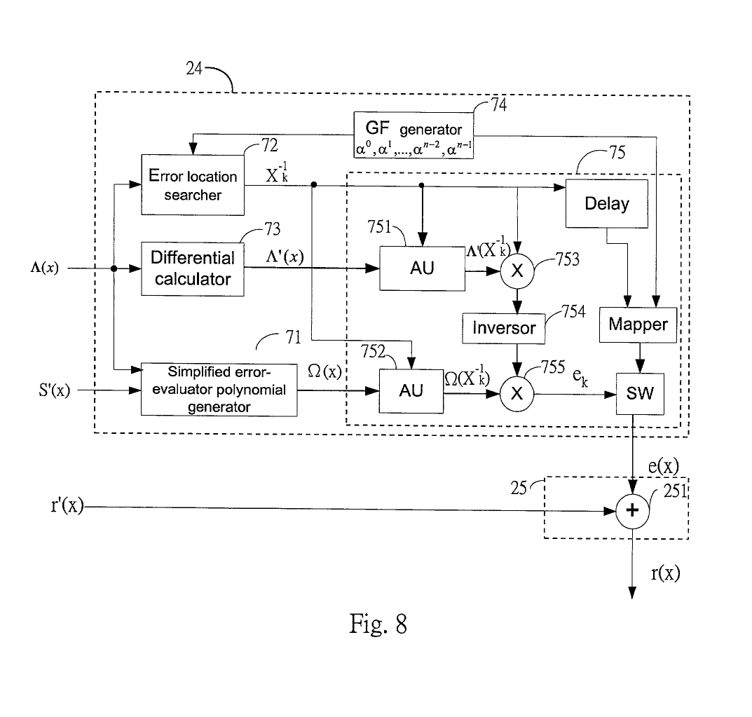

Please refer to FIG. 8 for further detailed description of the error magnitude calculator 75 of the error polynomial calculator 24 according to another embodiment of the present invention.

In the error magnitude calculator 75, two arithmetic units, 751 and 752, a multiplier 753, an inversor 754 (or named as a multiplicative inverse operator) and a multiplier 755 are mainly included. In the arithmetic unit 751, the inverse of the error location Xₖ⁻¹ and the derivative error locator polynomial Λ′(x) are introduced to calculate Λ′(Xₖ⁻¹). In the arithmetic unit 752, the inverse of the error location Xₖ⁻¹ and the simplified error-evaluator polynomial Ω(x) are introduced to calculate Ω(Xₖ₋₁). After multiplication and inversion calculation of the devices 753, 754 and 755 according the equation (2), the error magnitude eₖ is produced. The error polynomial e(x) is further generated based on the error magnitude eₖ.

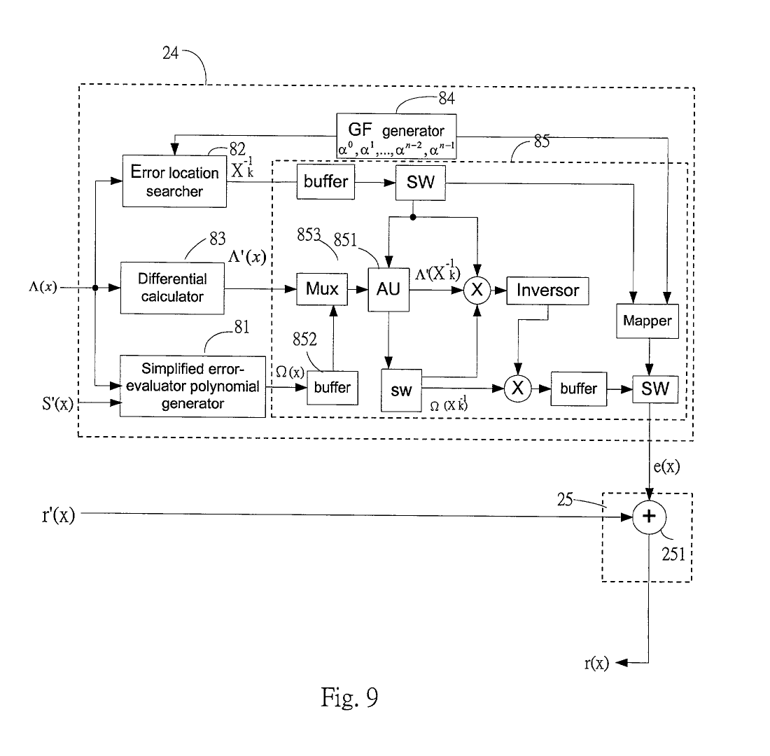

Please refer to FIG. 9 for further detailed description of the error polynomial calculator 24 according to still another embodiment of the present invention, particularly exemplifying that the required hardware devices can be reduced and calculation can be sped up according to the present invention.

In the simplified error polynomial calculator 24, a simplified error-evaluator polynomial generator 81, an error location searcher 82, a differential calculator 83, a GF generator 84 and an error magnitude calculator 85 are mainly included. In the error magnitude calculator 85, an arithmetic unit 851 is included to generate the Λ′(Xₖ⁻¹). Since the number of elements of the simplified error-evaluator polynomial Ω(x) is reduced, the number of arithmetic unit required can also be reduced. In addition, a buffer 852 in the error magnitude calculator 85 can be reduced in capacity since the number of elements of the simplified error-evaluator polynomial Ω(x) is reduced. A multiplexer 853 is incorporated to introduce the derivative error locator polynomial Λ′(x) and the simplified error-evaluator polynomial Ω(x) into the arithmetic unit 851.

According to the disclosure of the present invention, the Forney algorithm of the Reed-Solomon decoding can be simplified. Therefore, the Reed-Solomon decoding circuit and method of the present invention can be reduced in hardware devices and can perform better in speed.

The above detailed description is to clearly describe features and spirit of the present invention and is not intended to limit the scope of the present invention. Various changes and equivalent modifications should be covered by the invention. Therefore, the scope of the present invention should be interpreted based on the following claims together with the above descriptions in the broadest way.

What is claimed is:

1. A Reed-Solomon decoding circuit for decoding and correcting errors in a message encoded by a Reed-Solomon code having an error correcting capability of t, comprising:
a syndrome calculator, responsive to the message, for generating a syndrome polynomial of the message;
an error locator polynomial calculator, responsive to the syndrome polynomial, for generating an error locator polynomial;
a selector, responsive to the syndrome polynomial, for generating a reduced syndrome polynomial, each element of the reduced syndrome polynomial having an order less than a limit, wherein the limit is smaller than 2t;
a simplified error polynomial calculator, responsive to the error locator polynomial and the reduced syndrome polynomial, for generating an error polynomial; and
an error corrector, responsive to the error polynomial and the message, for generating a decoded message.

2. The Reed-Solomon decoding circuit of claim 1, wherein the simplified error polynomial calculator, responsive to the error locator polynomial and the reduced syndrome polynomial, further generates a simplified error-evaluator polynomial for the generation of the error polynomial; and each element of the simplified error-evaluator polynomial with an order higher than the limit minus one is eliminated.

3. The Reed-Solomon decoding circuit of claim 1, wherein the limit is t.

4. A Reed-Solomon decoding method for decoding and correcting errors in a message encoded by a Reed-Solomon code having an error correcting capability of t, comprising the steps of:
generating a syndrome polynomial of the message;
generating an error locator polynomial based on the syndrome polynomial;
generating a reduced syndrome polynomial, each element of the reduced syndrome polynomial having an order less than a limit minus one, wherein the limit is smaller than 2t;
generating a simplified error-evaluator polynomial based on the error locator polynomial and the reduced syndrome polynomial;
generating an error polynomial based on the error-evaluator polynomial; and
removing the error polynomial from the message to generate a decoded message.

5. The Reed-Solomon decoding method of claim 4, wherein each element of the simplified error-evaluator polynomial with an order higher than the limit minus one is eliminated.

6. The Reed-Solomon decoding method of claim 4, wherein the limit is t.
